(19) United States
(12) Patent Application Publication
(10) Pub. No.: US 2006/0027257 A1
(43) Pub. Date: Feb. 9, 2006

(54) Thermoelectric generator

(75) Inventors: Hiroo Yamaguchi, Toyohashi-city (JP); Yuuji Sako, Hazu-gun (JP); Hideyuki Iiboshi, Tokai-city (JP); Masanobu Katou, Toyoake-city (JP)

Correspondence Address: HARNESS, DICKEY & PIERCE, P.L.C., P.O. BOX 828, BLOOMFIELD HILLS, MI, 48303, US

(73) Assignee: DENSO Corporation, Kariya-city (JP)

(21) Appl. No.: 11/195,799

(22) Filed: Aug. 2, 2005

(30) Foreign Application Priority Data
Aug. 4, 2004 (JP) 2004-228407

(51) Int. Cl. H01L 35/28

(52) U.S. Cl. 136/203; 136/205

(57) ABSTRACT

A thermoelectric generator comprising: at least a high-temperature heat source using a high-temperature fluid; at least a low-temperature heat source using a low-temperature fluid lower in temperature than the high-temperature fluid; and a plurality of thermoelectric elements arranged in parallel between the high-temperature heat source and the low-temperature heat source; wherein at least selected one of the high-temperature heat source and the low-temperature heat source is connected with a frame surrounding the plurality of thermoelectric elements.

### BACKGROUND OF THE INVENTION

1. Field of the Invention

This invention relates to a thermoelectric generator for generating power, by the Seebeck effect, due to a temperature difference across thermoelectric elements.

2. Description of the Related Art

A conventional thermoelectric generator is disclosed in Japanese Unexamined Patent Publication No. 11-40863. In this generator a plurality of thermoelectric elements (thermoelectric generating modules) are arranged in parallel and are held between a high-temperature heat source (heat absorption structure on the high temperature side) and a low-temperature side heat source (heat radiation structure on the low temperature side), so that electric power is generated due to the temperature difference across the high-temperature heat source and the low-temperature heat source.

One of the surfaces of the high-temperature heat source and the low-temperature side heat source in contact with the thermoelectric elements is held integrally with an elastic flat plate, and a plurality of flat metal plates are independently coupled to each of a plurality of thermoelectric elements. A thickness variation, if any, in the thermoelectric elements is absorbed by the elastic flat plate, so that all the thermoelectric elements are in satisfactory thermal contact with each other.

In order to prevent the displacement of a plurality of the thermoelectric elements held by the high-temperature heat source and the low-temperature heat source, however, the thermoelectric elements are each coupled to a flat metal plate and, therefore, the assembly thereof requires considerable labor.

The patent document described above discloses the provision of a guide rib on the outer periphery of the flat metal plate to facilitate the positioning. The surface roughness and the flatness of the flat metal plate, however, may be deteriorated during the rib machining process, thereby adversely affecting the originally-intended satisfactory thermal contact.

### SUMMARY OF THE INVENTION

In view of the problem described above, the object of this invention is to provide a thermoelectric generator in which a plurality of thermoelectric elements are held between the high-temperature heat source and the low-temperature heat source while maintaining a satisfactory thermal contact with the high-temperature heat source and the low-temperature heat source, and the plurality of the thermoelectric elements can be assembled easily.

In order to achieve this object, according to this invention, there is provided a thermoelectric generator employing the technical means described below.

In order to accomplish the above object, according to a first aspect of the present invention, there is provided a thermoelectric generator comprising: at least a high-temperature heat source using a high-temperature fluid; at least a low-temperature heat source using a low-temperature fluid lower in temperature than the high-temperature fluid; and a plurality of thermoelectric elements arranged in parallel between the high-temperature heat source and the low-temperature heat source; wherein at least a selected one of the high-temperature heat source and the low-temperature heat source is connected with a frame surrounding the plurality of the thermoelectric elements.

Without deteriorating the surface roughness and the parallelism of the surfaces of each high-temperature heat source and each low-temperature heat source in contact with a plurality of thermoelectric elements, a satisfactory thermal contact is secured while making it possible to set a plurality of the thermoelectric elements in position, thereby eliminating the need to couple the plurality of the thermoelectric elements to the high-temperature heat source or the low-temperature heat source for an improved assembly performance.

The plurality of the thermoelectric elements are connected in series or in parallel to each other. In the case where the lead wires extending from the thermoelectric elements are twisted or brazed to each other or connected by connectors or the like, the lead wires from the thermoelectric elements project or otherwise hamper the assembly work. Under an external vibration load, on the other hand, stress is concentrated at the roots of the lead wires in view of the fact that the forward ends of the lead wires are free, thereby sometimes breaking the lead wires.

According to a second aspect of the present invention, the plurality of the thermoelectric elements are connected electrically to each other through a plurality of conducting portions arranged on the frame.

According to this invention, the unnecessary projection of the lead wires described above is eliminated, and the assembly work is thus eased. Also, as the lead wires are fixed on conducting portions, the risk of breakage under an external vibration load is eliminated.

In the second aspect of connection, as a third aspect of the present invention, the plurality of the conducting portions can be connected by brazing.

Moreover, as a fourth aspect of the present invention, the plurality of the conducting portions may be connected by inserting the lead wires of the plurality of the thermoelectric elements into holes formed in the conducting portions. As a result, the lead wires can be connected to the conducting portions by one touch while brazing is eliminated.

Moreover, according to a fifth aspect of the present-invention, the direction in which the lead wires are arranged and the holes are formed is coincident with the direction in which the plurality of the thermoelectric elements are inserted into the frame. As a result, The lead wires of the plurality of the thermoelectric elements can be inserted into holes while thermoelectric elements are inserted into the frame for an improved workability.

The present invention may be more fully understood from the description of preferred embodiments of the invention set forth below, together with the accompanying drawings.

### BRIEF DESCRIPTION OF THE DRAWINGS

FIG. 1 is a schematic diagram showing a general configuration including an engine.

FIG. 2 is an exploded perspective view showing a general configuration of a thermoelectric generator.

FIG. 3 is a plan view showing a frame according to a first embodiment.

FIGS. 4A, 4B are a plan view and a side view, respectively, showing the manner in which the lead wires of the thermoelectric elements arranged in the frame of FIG. 3 are connected to each other.

FIG. 5 is a plan view showing a frame according to a second embodiment.

FIGS. 6A, 6B are a plan view and a side view, respectively, showing the manner in which the lead wires of the thermoelectric elements arranged in the frame of FIG. 5 are connected to each other.

FIG. 7 is a sectional view taken in line A-A in FIG. 6.

### DESCRIPTION OF THE PREFERRED EMBODIMENTS

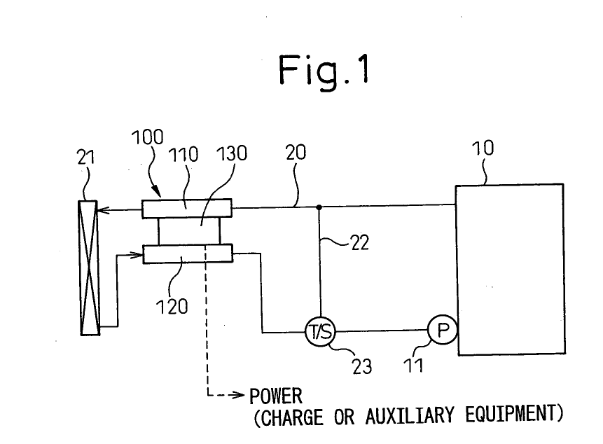

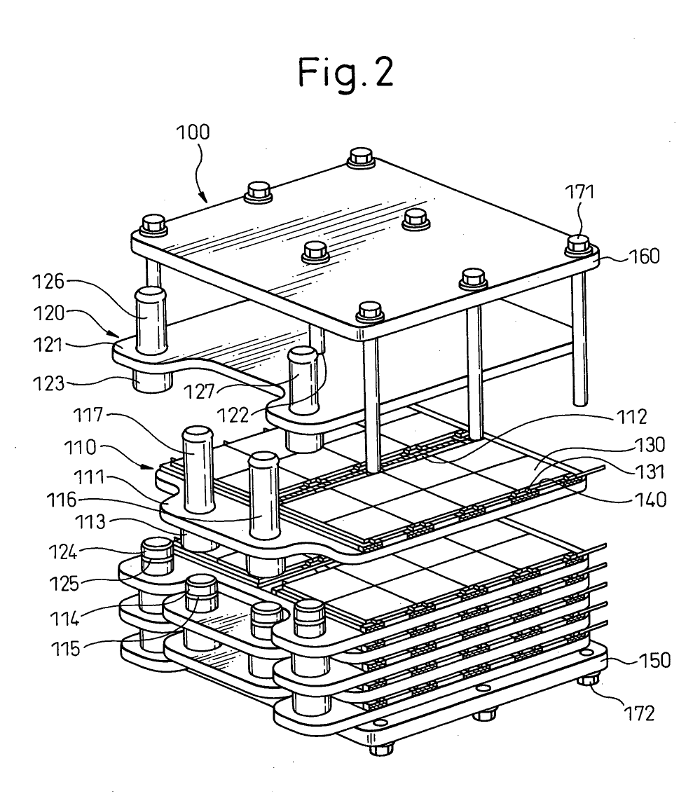

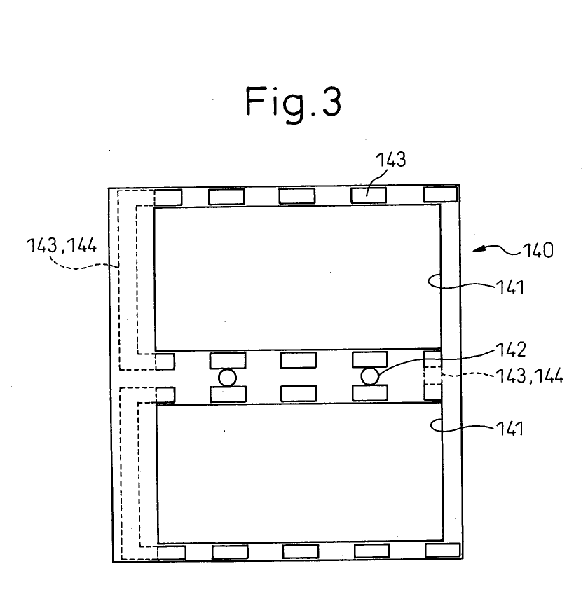

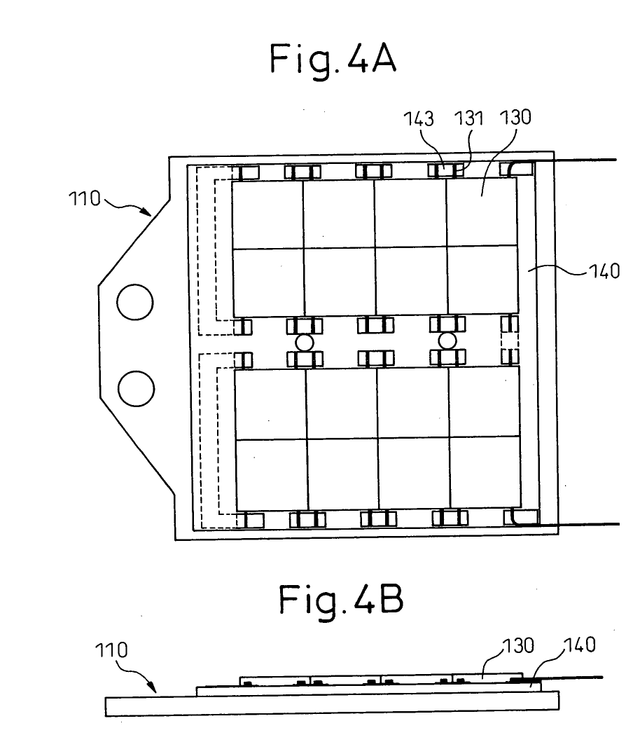

A first embodiment of the invention is explained. A thermoelectric generator 100 according to the invention is used for an automotive vehicle having a water-cooled engine 10, in which the waste heat energy generated by the cooling of the engine 10 is recovered as electric energy. First, the basic configuration of the thermoelectric generator 100 is explained with reference to FIGS. 1 to 4. In this connection, FIG. 1 is a schematic diagram showing a general configuration including an engine 10, FIG. 2 is an exploded perspective view showing a general configuration of a thermoelectric generator 100, FIG. 3 is a plan view showing a frame 140 according to a first embodiment, and FIGS. 4A, 4B are a plan view and a side view, respectively, showing the manner in which the lead wires 131 of the thermoelectric elements 130 arranged in the frame of FIG. 3 are connected to each other.

As shown in FIG. 1, the engine 10 includes an engine cooling water circuit 20 and a radiator 21. The cooling water in the engine 10 is circulated by a water pump 11 through the engine cooling water circuit 20 and the radiator 21. The heat radiation of the radiator 21 cools the cooling water and the operating temperature of the engine 10 is appropriately controlled. The engine cooling water circuit 20 includes a bypass 22 for bypassing the radiator 21 and a thermostat 23 for controlling the cooling water flow rate to the radiator 21 or the bypass 22.

The thermoelectric generator 100 is arranged between the radiator 21 and the bypass 22 in the engine cooling water circuit 20. The cooling water (the high-temperature water corresponding to the high-temperature fluid according to the invention) flowing out of the engine 10 flows through a high-temperature heat source 110 described later. The cooling water (the low-temperature water corresponding to the low-temperature fluid according to the invention) after passing through the radiator 21 flows through a low-temperature heat source 120 described later.

The thermoelectric generator 100 is explained in detail. As shown in FIG. 2, the thermoelectric generator 100 has a plurality of thermoelectric elements 130, which are disposed between the high-temperature heat sources 110 and the low-temperature heat sources 120 alternately stacked and which generate power utilizing the Seebeck effect. Three high-temperature heat sources 110, four low-temperature heat sources 120, and ninety-six thermoelectric elements 130 (sixteen between each pair of heat sources 110, 120 in six stages) are used as thirteen layers in all. A heat conductive grease is coated or a heat conductive sheet is interposed to decrease the contact heat resistance between each high-temperature heat source 110 and the corresponding thermoelectric elements 130 and between each low-temperature heat source 120 and the corresponding thermoelectric elements 130. The direction along which the heat sources 110, 120 are stacked is hereinafter called the vertical direction as in FIG. 2.

The high-temperature heat source 110 is a flat container formed of a pair of plates arranged center-to-center and peripherally molded. The high-temperature heat source 110 has an expansion 111 at an end thereof and bolt holes 112 for insertion of bolts 171 at the central portion thereof. An inner fin (not shown) to transmit the heat of the high-temperature water efficiently to the thermoelectric elements 130 is inserted in the high-temperature heat source 110.

As a basic form of the high-temperature heat source 110, large-diameter pipes 113 extending downward and small-diameter pipes 114 extending upward and adapted to be coupled to each other to communicate with the interior of the corresponding high-temperature heat source 110 are formed on the expansion 111. A circumferential groove is formed at the forward end of each small-diameter pipe 114 and has an O-ring 115 mounted therein.

Of the high-temperature heat sources 110 stacked in a plurality of layers, the uppermost stage includes a high-temperature inlet pipe 116 and a high-temperature outlet pipe 117 in place of the small-diameter pipes 114, and the lowest stage does not include a large-diameter pipe 113.

The low-temperature heat source 120 is different from the high-temperature heat source 110 in that the expansion 121 is located at such a position as to clear the expansion 111 of the high-temperature heat source 110, but is identical with the high-temperature heat source 110 in the other points. The low-temperature heat source 120 has a central bolt hole 122 in which an inner fin (not shown) is inserted to efficiently transmit heat to the low-temperature water from the thermoelectric elements 130. The expansion 121 includes large-diameter pipes 123 and small-diameter pipes 124 each carrying an O-ring 125. The low-temperature heat source 120 in the uppermost stage includes a low-temperature inlet pipe 126 and a low-temperature outlet pipe 127 in place of the small-diameter pipes 124, while the low-temperature heat source 120 in the lowest stage does not include a large-diameter pipe 123.

The thermoelectric element 130 is well known and generates power using the Seebeck effect (or generates heat using the Peltier effect). It is formed of a P-type semiconductor and a N-type semiconductor connected in series by a metal electrode. The lead wires 131 for connecting the P-type semiconductor and the N-type semiconductor are projected from an end of the thermoelectric element 130 at two points. Each thermoelectric element 130 is in the shape of a square having each side of about 40 mm, and sixteen thermoelectric elements 130 are arranged in parallel (in one plane) between each pair of the high-temperature heat source 110 and the low-temperature heat source 120. The thermoelectric elements 130 are connected in series by the lead wires 131 (the connecting method is described in detail later).

According to this invention, a frame 140 is arranged to position and connect the plurality of the corresponding thermoelectric elements 130. Each frame 140, which is made of a resin material has, as shown in FIG. 3, a profile of a square smaller than the heat sources 110, 120 and a thickness smaller than the thermoelectric elements 130 (about one half as thick as the thermoelectric elements 130). Two openings 141 are formed in the frame 140, and eight thermoelectric elements 130 are inserted closely in each opening 141 (the frame 140 surrounds a plurality of the thermoelectric elements 130).

Two bolt holes 142 corresponding to the bolt holes 112, 122 of the heat sources 110, 120 are formed between the two openings 141. Incidentally, a cylindrical protrusion to be inserted into the bolt holes 112, 122 of the opposed heat sources 110, 120 is formed on the outer periphery of each bolt hole 142, so that the frame 140 and the heat sources 110, 120 can be set in position at the time of assembly.

A plurality of conducting portions 143 of copper plates are coupled on the outer periphery of the frame 140 and at positions between the openings 141 corresponding to the lead wires 131 of the thermoelectric elements 130. This frame 140 makes up a printed board. In the middle stage on the left and right sides in FIG. 3, the conducting portions 143 extend in vertical direction, and an insulating portion 144 of a coating material is formed on the surface of the intermediate portion (indicated by dashed line in FIG. 3) of each conducting portion for insulation from the exterior.

Using the frames 140, the thermoelectric generator 100 is assembled in the following way. Specifically, as shown in FIGS. 4A, 4B, the frame 140 is arranged on the upper side surface of each of the heat sources 110, 120 and coupled by adhesive or the like. In the process, as described above, the frame 140 is positioned by the bolt holes 112, 122, 142 with respect to the heat sources 110, 120.

Next, sixteen thermoelectric elements 130 are inserted into the openings 141 of each frame 140 in such a manner that the lead wires 131 and the conducting portions 143 coincide with each other in position. Each lead wire 131 is soldered (or brazed according to the invention) to the corresponding conducting portion 143, after which the surface of the lead wires 131 is subjected to a waterproofing process with a silicon agent or the like. The sixteen thermoelectric elements 130 are positioned on each frame 140 on the upper side surface of the heat sources 110, 120 while at the same time being connected in series (electrically connected).

Next, as shown in FIG. 2, the low-temperature heat sources 120 (having mounted the thermoelectric elements 130 thereon) and the high-temperature heat sources 110 (having mounted the thermoelectric elements 130 thereon) are stacked alternately with each other from the lower side, and the low-temperature heat source 120 (having mounted no thermoelectric element 130 thereon) is set in the uppermost stage. In the process, the small-diameter pipes 124 of a given low-temperature heat source 120 are inserted into the large-diameter pipes 123 of the low-temperature heat source 120 in the immediately upper stage, and both are connected by the O-ring 125 interposed between the inner peripheral surface of each large-diameter pipe 123 and the outer peripheral surface of the corresponding small-diameter pipe 124. The large-diameter pipes 123, the small-diameter pipes 124 and the O-rings 125 thus establish communication between the plurality of the low-temperature heat sources 120, and the low-temperature inlet pipe 126 and the low-temperature outlet pipe 127 are opened to the upper side of the uppermost low-temperature heat source 120.

In similar fashion, the small-diameter pipes 114 of a given high-temperature heat source 110 is inserted into the large-diameter pipes 113 of the high-temperature heat source 110 in the immediately upper stage, and both are connected to each other through the O-rings 115. The large-diameter pipes 113, the small-diameter pipes 114 and the O-rings 115 establish mutual communication between the plurality of the high-temperature heat sources 110, with the high-temperature inlet pipe 116 and the high-temperature outlet pipe 117 open to the upper side of the uppermost high-temperature heat source 110.

Next, a lower plate 150 is set under the lowermost stage of the low-temperature heat source 120, and an upper plate 160 above the uppermost stage of the low-temperature heat source 120. A plurality of the high-temperature heat sources 110, the low-temperature heat sources 120 and the thermoelectric elements 130 are held between the upper plate 160 and the lower plate 150 and integrally fixed with each other by bolts 171 and nuts 172. A thermoelectric generator 100 in which the thermoelectric elements 130 are in opposed relation with the heat sources 110, 120 under a predetermined surface pressure is thus formed.

The high-temperature inlet pipe 116 and the high-temperature outlet pipe 117 of the thermoelectric generator 100 are connected to the upstream side of the radiator 21 of the engine cooling water circuit 20. The low-temperature inlet pipe 126 and the low-temperature outlet pipe 127, on the other hand, are connected to the downstream side of the radiator 21.

In the thermoelectric generator 100 described above, after starting the engine 10, the cooling water increases in temperature and exceeds a predetermined temperature (say, 90° C.), and thermostat 23 opens to the radiator 21. Then, the high-temperature water flowing out of the engine 10 flows into the plurality of the high-temperature heat sources 110 through the high-temperature inlet pipe 116 of the thermoelectric generator 100 and flows into the radiator 21 through the high-temperature outlet pipe 117.

The low-temperature water that has passed through the radiator 21 flows through a plurality of the low-temperature heat sources 120 from the low-temperature inlet pipe 126, and returns to the engine 10 through the low-temperature outlet pipe 127.

The plurality of the thermoelectric elements 130 are subjected to a temperature difference due to the high-temperature water flowing through the high-temperature heat sources 110 and the low-temperature water flowing through the low-temperature heat sources 120, so that power is generated with a predetermined power generation capacity. The electric power produced by this power generating operation is stored in a battery charger (battery) not shown or used for the operation of various auxiliary equipment.

As long as the cooling water remains at lower than a predetermined temperature (say, 90° C.), the radiator 21 is closed by the thermostat 23, and the cooling water flows through the bypass 22 thereby to promote the warming-up of the engine 10.

As described above, in the thermoelectric generator 100 with a plurality of the thermoelectric elements 130 interposed between each pair of the heat sources 110, 120, the assembly work thereof consumes a considerable labor. According to this invention, however, the provision of the frames 140 makes it possible to set a plurality of the thermoelectric elements 130 in position while at the same time securing a satisfactory thermal contact with the plurality of the high-temperature heat sources 110 and the low-temperature heat sources 120 without adversely affecting the surface roughness and parallelism of the contact surface of the high-temperature heat sources 110 and the low-temperature heat sources 120 with the thermoelectric elements 130. Thus, the connection of the plurality of the thermoelectric elements 130 to the high-temperature heat sources 110 or the low-temperature heat sources 120 as explained in “Description of the Related Art” is eliminated to provide an improved assembly performance.

Further, the plurality of the thermoelectric elements 130 are connected to each other by soldering through a plurality of the conducting portions 143 arranged on each frame 140. Therefore, the protrusion of each lead wire 131 and, hence, an obstacle to the assembly work are eliminated. Also, the lead wires 131 are fixed on the conducting portions 143 and therefore not easily broken under an external vibration load.

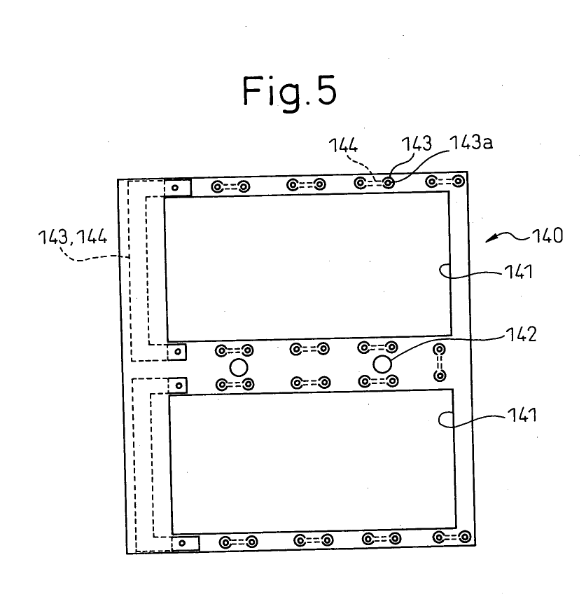

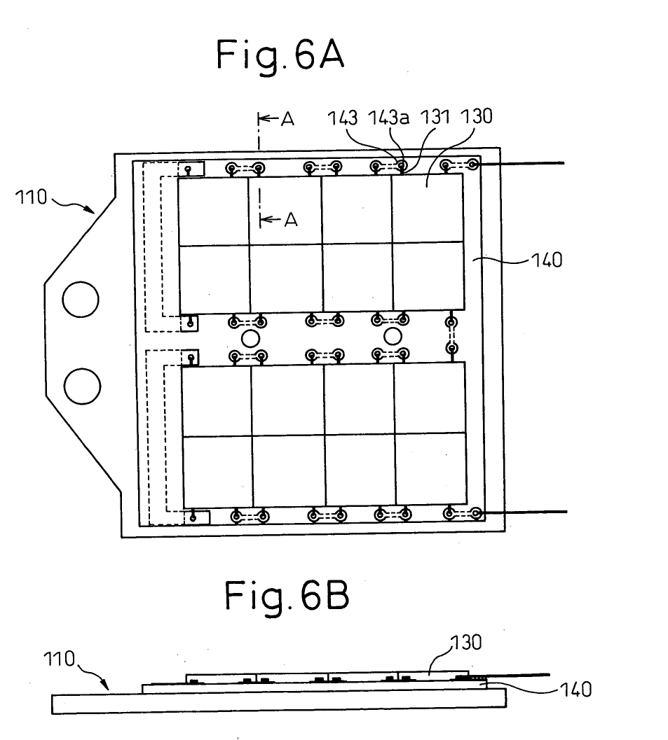

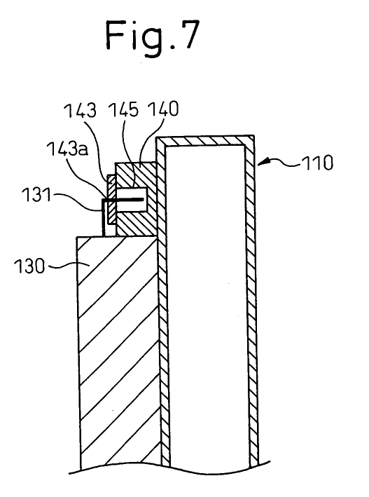

Next, a second embodiment of the invention is explained with reference to FIGS. 5 to 7. In the second embodiment, the method of connecting the lead wires 131 is different from the first embodiment.

Specifically, the conducting portions 143 of each frame 140 are formed with holes 143a through which the lead wires 131 of the thermoelectric elements 130 are inserted. In addition, the frame 140 is formed with lower holes 145 corresponding to the holes 143a. The direction in which the holes 143a and the lower holes 145 are formed is coincident with the direction in which the thermoelectric elements 130 are inserted into the openings 141 of the frame 140 (the direction in which the heat sources 110, 120 are stacked). Also, the forward end of each lead wire 131 of the thermoelectric elements 130 is bent into the same direction as the direction in which the holes 143a and the lower holes 145 are formed.

At the time of mounting the thermoelectric elements 130, the thermoelectric elements 130 are inserted into the openings 141 of each frame 140, while at the same time fitting by inserting the lead wires 131 into the holes 143a (lower holes 145) (mechanical connection).

As a result, the soldering is eliminated unlike in the first embodiment, and the lead wires 131 can be connected to the conducting portions 144 by one action for an improved workability.

The direction of the lead wires 131 and the holes 143a is not limited to those in the embodiments described above, but may be changed as required by the restrictions of design or fabrication.

Finally, other embodiments are explained. According to the first and second embodiments, the cooling water (high-temperature water) flowing out of the engine 10 in the engine cooling water circuit 20 and the cooling water (low-temperature water) after passing through the radiator 21 are used as the high- and low-temperature fluids, respectively, of the thermoelectric generator 100. Alternatively, the exhaust gas of the engine 10 may be used as the high-temperature fluid, and cooling water in an exclusive cooling water circuit other than the engine cooling water circuit 20 may be used as the low-temperature fluid.

Also, in the embodiments explained above, a plurality of the heat sources 110, 120 are stacked to hold a plurality of sets of the thermoelectric elements 130. As an alternative, the thermoelectric elements 130 may be held by one high-temperature heat source 110 and one low-temperature heat source 120 with equal effect.

While the invention has been described by reference to specific embodiments chosen for purposes of illustration, it should be apparent that numerous modifications could be made thereto by those skilled in the art without departing from the basic concept and scope of the invention.

1. A thermoelectric generator comprising:
at least a high-temperature heat source using a high-temperature fluid;
at least a low-temperature heat source using a low-temperature fluid lower in temperature than the high-temperature fluid; and
a plurality of thermoelectric elements arranged in parallel between the high-temperature heat source and the low-temperature heat source;
wherein at least a selected one of the high-temperature heat source and the low-temperature heat source is connected with a frame surrounding the plurality of the thermoelectric elements.

2. A thermoelectric generator according to claim 1,
wherein the plurality of the thermoelectric elements are connected electrically to each other through a plurality of conducting portions arranged on the frame.

3. A thermoelectric generator according to claim 2,
wherein the plurality of the conducting portions are connected by brazing.

4. A thermoelectric generator according to claim 2,
wherein the plurality of the conducting portions are connected by inserting the lead wires of the plurality of the thermoelectric elements into holes formed in the conducting portions.

5. A thermoelectric generator according to claim 4,
wherein the direction in which the lead wires are arranged and the holes are formed is coincident with the direction in which the plurality of the thermoelectric elements are inserted into the frame.
